(19) United States
(12) Patent Application Publication
(10) Pub. No.: US 2009/0108424 A1
(43) Pub. Date: Apr. 30, 2009

(54) LEADFRAME FOR LEADLESS PACKAGE

(75) Inventors: HENG CHANG KUO, TAINAN COUNTY (TW); PO KAI HOU, TAINAN COUNTY (TW); CHUN YING LIN, TAINAN COUNTY (TW)

Correspondence Address: WPAT, PC;INTELLECTUAL PROPERTY ATTORNEYS, 2030 MAIN STREET, SUITE 1300, IRVINE, CA, 92614, US

(73) Assignee: CHIPMOS TECHNOLOGIES INC., HSINCHU (TW)

(21) Appl. No.: 12/248,391

(22) Filed: Oct. 9, 2008

(30) Foreign Application Priority Data
Oct. 31, 2007 (TW) 096140896

(51) Int. Cl. H01L 23/495

(52) U.S. Cl. 257/676; 257/E23.031

(57) ABSTRACT

A leadframe for a leadless package comprises a plurality of package areas, a plurality of first slots, a plurality of first side rails, a plurality of second side rails, and tape. Each of the package areas comprises a plurality of package units, each of which comprises a die pad and a plurality of leads surrounding the die pad. The plurality of first side rails and the plurality of second side rails are connected and surround the plurality of the package areas. The tape fixes the plurality of package areas, the plurality of first side rails, the plurality of second side rails, the die pads, and the plurality of leads in place.

### BACKGROUND OF THE INVENTION

(A) Field of the Invention

The present invention relates to a leadframe for a leadless package, and more particularly, to a leadframe used by a Quad Flat Non-leaded package (QFN).

(B) Description of the Related Art

The trends of current consumer electronics have focused on minimal weight and compact size. Accordingly, the QFN package is currently being applied to the traditional leaded package, and has successfully replaced the more expensive wafer level CSP (chip scale package). The CSP has reduced the size of the package to approximately the size of the chip, but it requires fine-pitch tin ball grid arrays acting as terminals of the package so that the difficulty in manufacturing such a precision package is very high. In contrast, the QFN package is not only compact in size, low in cost, and high in yield, but can also provide advantages in coplanarity and cooling performance especially for high-speed and power management circuits. Furthermore, the QFN package does not require any pin leads extending from the sides of its package body, and therefore has better electrical performances than the traditional package that requires a plurality of leads extending from its sides. For example, the SO (single outline) series lead package or QFP (Quad Flat package) series lead package both require leads at their sides, and, like an antenna, the leads are likely to bring noise interference in high frequency applications.

FIG. 1 is a top view showing the semi-finished product of a conventional QFN package 10. The leadframe 12 comprises a plurality of package areas 11, each of which comprises a plurality of package units 112 arranged as an array. The saw streets 113 and 114 surround the package units 112, and a cutter can pass through these streets to divide the package units 112 into individual components. Meanwhile, the cutter cuts the supporting bars (not shown) connected to the package 111 and leadframe 12.

FIG. 2 is an illustration showing the singulation process of a conventional QFN package. A cutting blade 80 cuts the QFN package 10 along the saw streets 113 and 114 to isolate each of the package units 112, and, the edge of the cutting blade 80 is required to cut off the package 111 and leadframe 12 simultaneously. In general, the material of the common packages 111 is a compound of epoxy, silicon particle fillers, and hardener, and the leadframe 12 is made from a metallic alloy. The edge of the cutting blade 80 comprises resin bond and diamond dots thereon, but it cannot have good cutting performance on both the package 111 and the metallic leadframe 12. When cutting through the leadframe 12, the cutting blade 80 experiences more wear. The lifespan of the cutting blade 80 is reduced due to cutting metallic materials, and consequently the frequency of cutting tool replacement increases. If the cutting speed is decreased in order to reduce the wear of the cutting blade 80, then the units per hour (UPH) of the cutting process is reduced so that the advantage of mass production is lessened. Apparently, the conventional QFN package still has aforesaid existing problems that remain to be resolved.

### SUMMARY OF THE INVENTION

One aspect of the present invention provides a leadframe for a leadless package, wherein a plurality of gaps or slots surrounding each of the package units act as sawing streets for a singulation process, thereby reducing the wear of the cutting tools and improving cutting efficiency.

Another aspect of the present invention provides a leadframe for improving production efficiency. A plurality of gaps or slots located at a plurality of side rails of the leadframe align with sawing streets to effectively reduce the metal cutting paths of a cutting tool during a singulation process, thereby improving the production efficiency of the package manufacturing.

Yet another aspect of the present invention provides a leadframe with superior structural rigidity for a leadless package. An insulating material is filled in a plurality of slots on a plurality of side rails of the leadframe to improve the structural integrity of the leadframe. When the leadframe is picked and placed, it can be effectively transferred without risk of damage. In view of the above aspects, the present invention provides a leadframe for a leadless package. The leadframe comprises a plurality of package areas, a plurality of first slots, a plurality of first side rails, a plurality of second side rails, and a tape (film). Each package area comprises a plurality of package units, each of which comprises a die pad and a plurality of leads surrounding the die pad. The plurality of first side rails and plurality of second side rails are connected to each other and surround the plurality of package areas. The tape (film) fixes the plurality of package areas, the plurality of first side rails, and the plurality of second side rails in place.

### BRIEF DESCRIPTION OF THE DRAWINGS

The objectives and advantages of the present invention will become apparent upon reference to the following description and the accompanying drawings in which:

FIG. 1 is a top view showing the semi-finished product of a conventional QFN package 10;

FIG. 2 is an illustration showing the singulation process of a conventional QFN package;

FIG. 3 is a top view showing a leadframe for a leadless package in accordance with one embodiment of the present invention;

FIG. 4(a) is a top view showing a leadframe for leadless package in accordance with another embodiment of the present invention;

FIG. 4(b) is a cross-sectional illustration along the line A-A in FIG. 4(a);

FIG. 4(c) is an illustration showing a second slot in accordance with another embodiment of the present invention;

FIG. 5(a) is a top view showing a leadframe for a leadless package in accordance with one embodiment of the present invention;

FIG. 5(b) is a top view showing a leadframe for a leadless package in accordance with one embodiment of the present invention;

FIG. 6(a) is a top view showing a leadframe for a leadless package in accordance with one embodiment of the present invention; and

FIGS. 6(b)-6(c) are cross-sectional illustrations along the line B-B in FIG. 6(a).

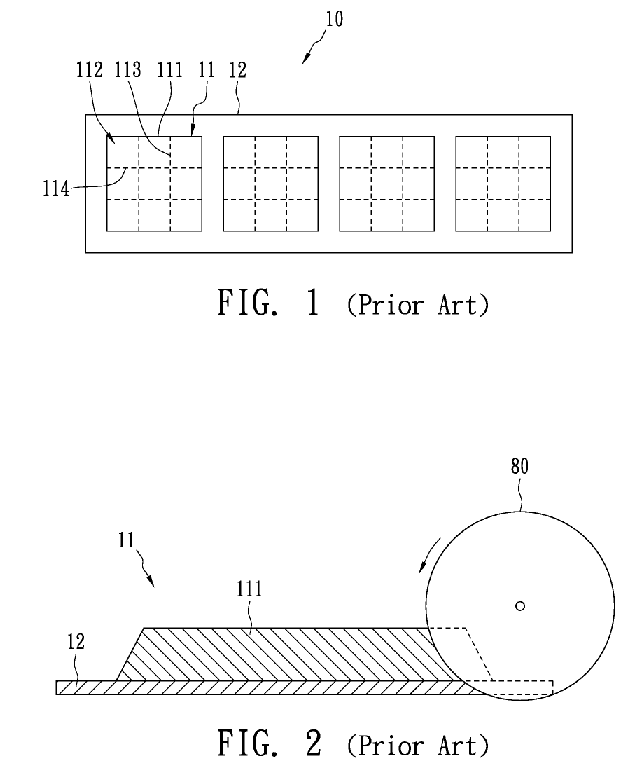

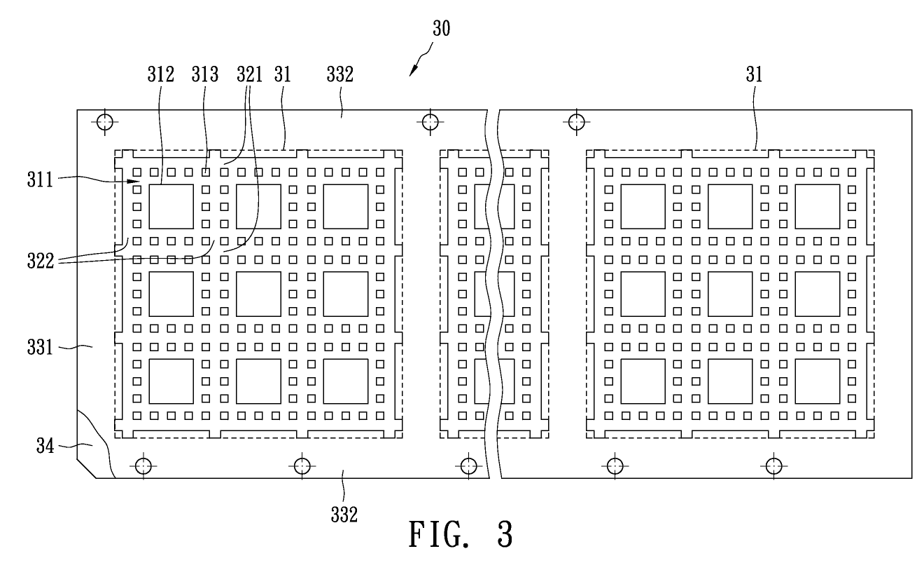

### DETAILED DESCRIPTION OF THE INVENTION

FIG. 3 is a top view showing a leadframe for a leadless package in accordance with the present invention. A leadframe 30 comprises a plurality of package areas 31, a plurality of first slots 321 and 322, a plurality of first side rails 331, a plurality of second side rails 332, and a tape (film) 34. Each of the package areas 31 comprises a plurality of package units 311 arranged in a matrix. The plurality of first slots 321 and 322 surround each of the package units 311, and the first slots 321 and 322 are located on sawing streets. The first slots 321 extend along the longitudinal direction of the leadframe 30, and the first slots 322 extend along the transverse direction of the leadframe 30 and are connected to the second frame 332. The plurality of first side rails 331 and plurality of second side rails 332 are connected to each other, and surround the plurality of the package areas 31. Each of the package units 311 comprises at least one die pad 312 and leads 313 surrounding the die pad 312. The tape 34 holds the plurality of package areas 31, the plurality of first side rails 331, the plurality of second side rails 332, die pads 312, and leads 313 in place.

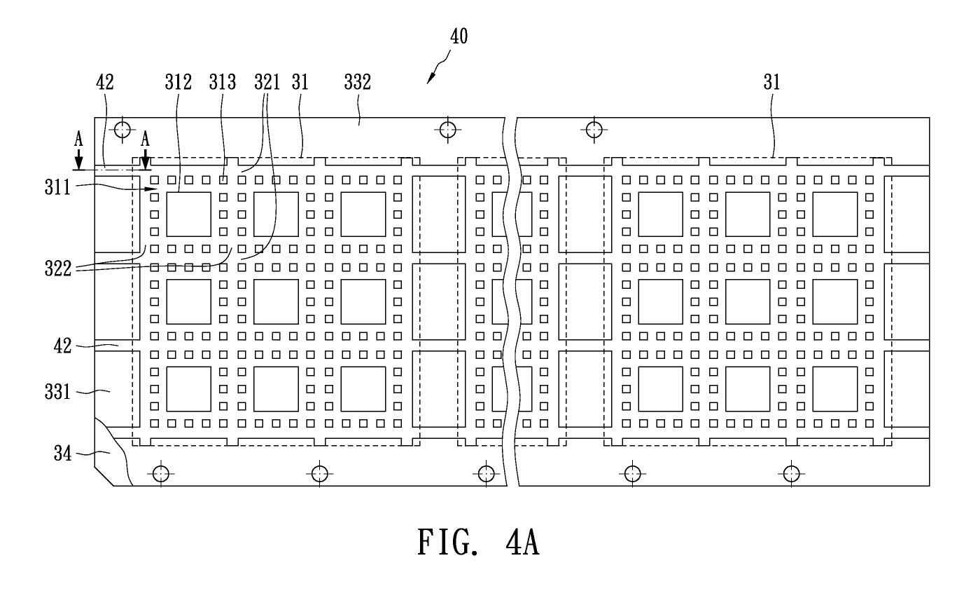

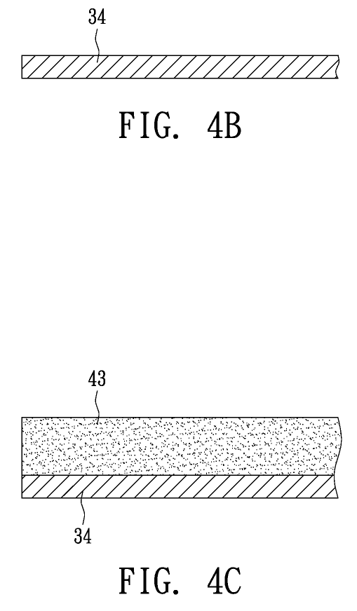

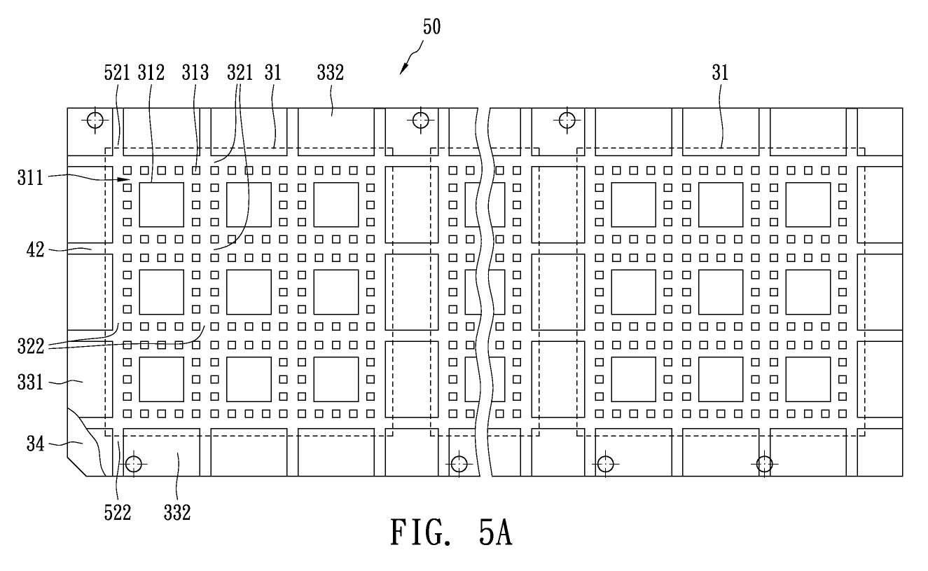

FIG. 4(a) is a top view showing a leadframe for leadless package in accordance with another embodiment of the present invention. Compared with FIG. 3, the first side rails 331 of a leadframe 40 comprise a plurality of second slots 42, each of which is connected to one of the first slots 321 individually. This embodiment helps to reduce the metal cutting paths of a cutting tool during cutting of the leadframe 40.

FIG. 4(b) is a cross-sectional illustration along the line A-A in FIG. 4(a). Second slots 42 pass through the first frame 331, and the tape 34 exists under the second slots 42. Compared with FIG. 4(b), there is an insulation layer 43 filling the second slot 42 in FIG. 4(c), thereby improving the structural rigidity of the leadframe.

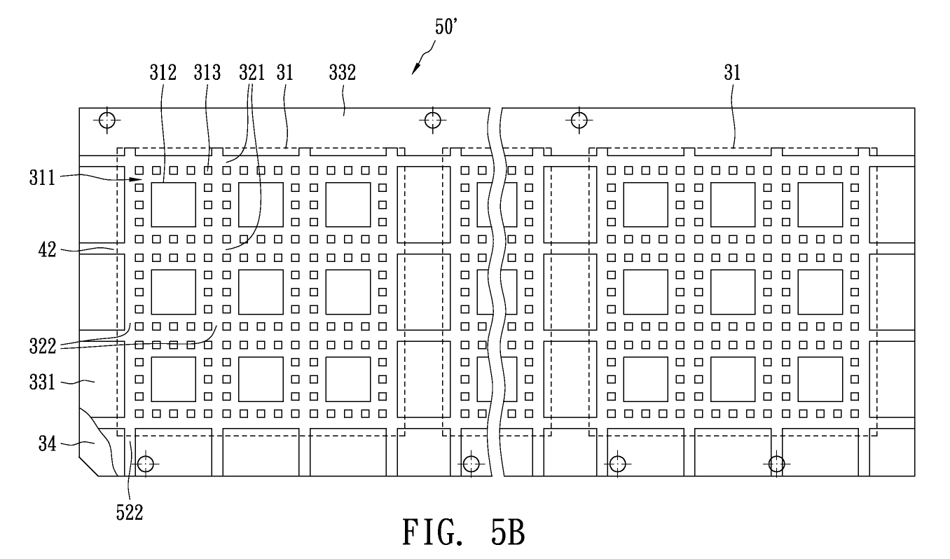

FIG. 5(a) is a top view showing a leadframe for a leadless package in accordance with one embodiment of the present invention. A leadframe 50 comprises a plurality of package areas 31, a plurality of first slots 321 and 322, a plurality of first side rails 331, a plurality of second side rails 332, and a tape 34. Each of the package areas 31 comprises a plurality of package units 311 arranged in a matrix. The plurality of first slots 321 and 322 surround each of the package units 311, and the first slots 321 and 322 are located on sawing streets. The first slots 321 extend along the longitudinal direction of the leadframe 50, and the first slots 322 extend along the transverse direction of the leadframe 50, and are connected to the second frame 332. The plurality of first side rails 331 and the plurality of second side rails 332 are connected to each other, and surround the plurality of the package areas 31. Each of the package units 311 comprises at least one die pad 312, and the leads 313 are located around the die pad 312. The first side rail 331 comprises a plurality of second slots 42, each of which respectively is connected to one of the first slots 321. The upper and lower second side rails 332 opposite to each other respectively comprise a plurality of third slots 521 and 522. The third slots 521 and 522 are connected to one of the first slots 322. The tape 34 holds the plurality of package areas 31, the plurality of first side rails 331, the plurality of second side rails 332, die pad 312, and leads 313 in place.

If the upper second side rail 332 is designed as the base of runners and gates during a molding process, then the third slots 521 cannot be provided on the upper second side rail 332 of the leadframe 50′, as shown in FIG. 5(b).

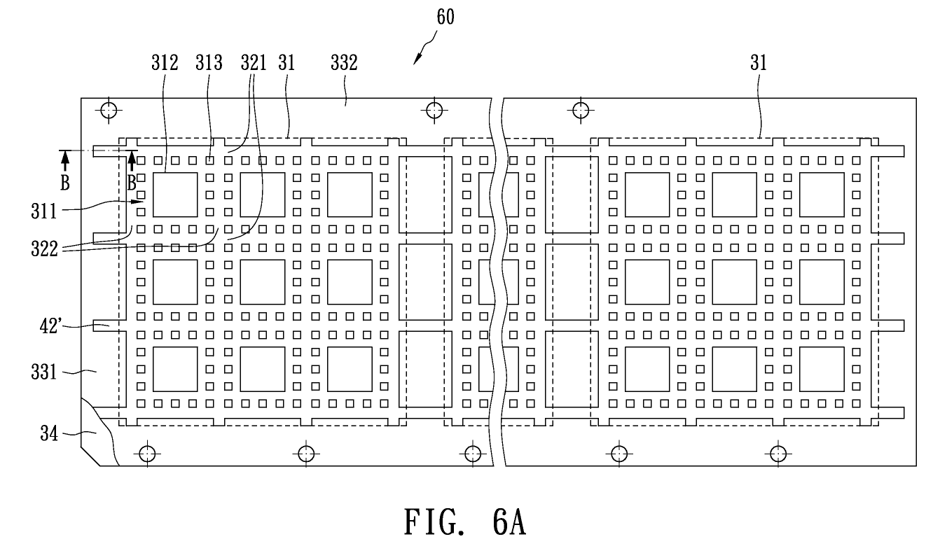

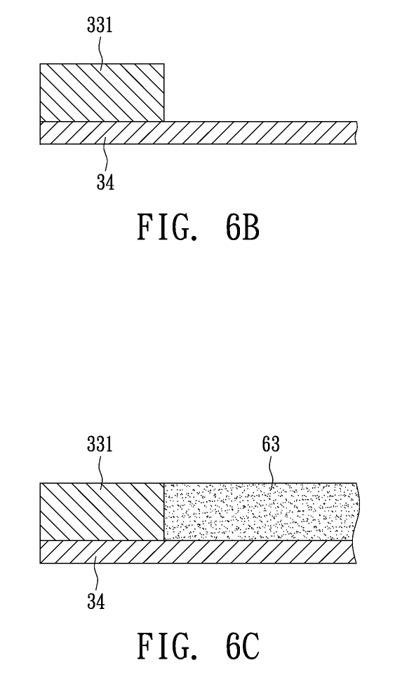

FIG. 6(a) is a top view showing a leadframe for a leadless package in accordance with one embodiment of the present invention. As shown in this illustration, the second slot 42′ of a leadframe 60 passes through the borders of the package area 31, and extends within one of the first side rails 331 but does not reach to the edge of the first side rail 331.

FIGS. 6(b)-6(c) are cross-sectional illustrations along the line B-B in FIG. 6(a). The second slot 42′ does not reach the edge of the first side rail 331. The second slot 42′ can be filled with an insulation layer 63 to improve the structural integrity of the leadframe 60.

The above-described embodiments of the present invention are intended to be illustrative only. Numerous alternative embodiments may be devised by those skilled in the art without departing from the scope of the following claims.

What is claimed is:

1. A leadframe for a leadless package, comprising:
a plurality of package areas, each of which comprises a plurality of package units;
a plurality of first slots surrounding each of the package units;
a plurality of first side rails;
a plurality of second side rails connected to the plurality of first side rails, wherein the plurality of first side rails and the plurality of second side rails surround the plurality of the package areas; and
a tape fixing the plurality of package areas, the plurality of first side rails, and the plurality of second side rails.

2. The leadframe for a leadless package of claim 1, wherein the plurality of first slots extend to the border of each of the package areas.

3. The leadframe for a leadless package of claim 1, wherein the plurality of first slots pass through the border of the package areas and extend to each of the first side rails and second side rails.

4. The leadframe for a leadless package of claim 3, wherein the plurality of first slots extend to edges of each of the first side rails and second side rails.

5. The leadframe for a leadless package of claim 3, wherein portions of the plurality of first slots extending to the first side rails and second side rails are filled with an insulation filling layer.

6. The leadframe for a leadless package of claim 1, wherein the length of the first side rail is smaller than the length of the second side rail.

7. The leadframe for a leadless package of claim 6, further comprising a plurality of second slots passing through the plurality of the first side rails, wherein the plurality of second slots are respectively connected to some of the plurality of the first slots.

8. The leadframe for a leadless package of claim 6, further comprising a plurality of third slots passing through the plurality of the second side rails, wherein the plurality of third slots are respectively connected to some of the plurality of the first slots.

9. The leadframe for a leadless package of claim 6, further comprising a plurality of third slots passing through one of the plurality of second side rails, wherein the plurality of the third slots are respectively connected to some of the plurality of the first slots.

10. The leadframe for a leadless package of claim 9, wherein the second side rail not passed through by the plurality of the third slots serves as a base of runners and gates during a molding process.

11. The leadframe for a leadless package of claim 1, wherein each of the package units comprises a die pad and a plurality of leads surrounding the die pad.

12. The leadframe for a leadless package of claim 1, wherein the plurality of package units are arranged in a matrix.

13. The leadframe for a leadless package of claim 1, wherein the plurality of first slots separates the plurality of package units from each other.

14. The leadframe for a leadless package of claim 1, wherein the plurality of first side rails are located at opposing sides.

15. The leadframe for a leadless package of claim 1, wherein the plurality of second side rails are located at opposing sides.
